(19) United States
(12) Patent Application Publication
(10) Pub. No.: US 2025/0151573 A1
(43) Pub. Date: May 8, 2025

(54) Display Device

(71) Applicant: LG Display Co., Ltd., Seoul (KR)

(72) Inventors: Hee Jung Yang, Paju-si (KR); Young Wook Lee, Paju-si (KR)

(21) Appl. No.: 18/929,147

(22) Filed: Oct. 28, 2024

(30) Foreign Application Priority Data
Nov. 2, 2023 (KR) 10-2023-0150149

(51) Int. Cl. H10K 59/80; H10K 59/124

(52) U.S. Cl. CPC H10K 59/80515; H10K 59/124

(57) ABSTRACT

A display device and a method of repairing the display device is disclosed. The display device includes a substrate and a plurality of sub-pixels arranged on the substrate. A sub-pixel includes an emissive area and a circuit area, a first overcoat layer on the substrate, a 1-1 electrode arranged on the first overcoat layer, a second overcoat layer covering at least a portion of the 1-1 electrode, and a 1-2 electrode arranged on the second overcoat layer, a light emitting layer on the 1-1 electrode, the 1-2 electrode and the second overcoat layer, and a cathode electrode on the light emitting layer.

### CROSS-REFERENCE TO RELATED APPLICATION

This application claims priority from Republic of Korea Patent Application No. 10-2023-0150149 filed on Nov. 2, 2023, which is hereby incorporated by reference in its entirety.

### BACKGROUND

### Field

Embodiments of the disclosure relate to a display device and a display device repair method.

### Description of Related Art

With the development of the information society, the demand for image display devices is increasing in various forms. Representative examples of such display devices include liquid crystal devices (LCD) and organic light emitting display devices (OLED).

The process of fabricating display panels includes deposition and repair processes. The deposition process is a process that deposits conductive layers, metal layers, insulating layers, and the like on a substrate to form structures such as devices (including electrodes), power lines, signal lines, and the like. The repair process is a process that repairs defects in the structure formed on the substrate or darkens sub-pixels where defects exist.

### SUMMARY

Repair methods proposed in the related art suffer from a loss of aperture ratio (or transmittance) and require cutting or removal of structures used in the repair process, which requires improvements to increase product yield and process tact time.

Accordingly, the inventors of the present disclosure have disclosed a display device that is capable of improving product yield while minimizing or at least reducing aperture ratio reduction.

The challenges of the present disclosure are not limited to those mentioned above, and other challenges not mentioned will be apparent to those skilled in the art from the following description.

In one embodiment, a display device comprises: a substrate; a plurality of sub-pixels on the substrate, the plurality of sub-pixels comprising a sub-pixel including an emissive area and a circuit area; a first overcoat layer on the substrate; a first sub anode electrode on the first overcoat layer; a second overcoat layer on a portion of the first sub anode electrode that is in the emissive area; a second sub anode electrode on the second overcoat layer in the emissive area, the second sub anode electrode overlapping the first sub anode electrode in the emissive area; an organic light emitting layer covering the first sub anode electrode, the second overcoat layer, and the second sub anode electrode in the emissive area; and a cathode electrode on the organic light emitting layer in the emissive area.

In one embodiment, a display device comprises: a substrate having an emissive area in which an image is displayed and a circuit area; a transistor on the circuit area of the substrate; a first overcoat layer on the emissive area and the circuit area such that the first overcoat layer is over the transistor in the circuit area; a first sub anode electrode in at least the emissive area, the first sub anode electrode connected to the transistor; a second overcoat layer on a portion of the first sub anode electrode in the emissive area without the second overcoat layer extending to the circuit area, the second overcoat layer including an upper surface and an inclined side surface that extends from the upper surface to the first sub anode electrode; a second sub anode electrode that is on the upper surface of the second overcoat layer in the emissive area; a light emitting layer over the second sub anode electrode and the second overcoat layer in the emissive area, the light emitting layer including a first inclined portion having an end that contacts a portion of the first sub anode electrode in the emissive area and extends toward the upper surface of the second overcoat layer along the inclined side surface of the second overcoat layer, and a second portion that extends from the first inclined portion of the light emitting layer and contacts the second sub anode electrode and the upper surface of the second overcoat layer; and a cathode electrode on the light emitting layer in the emissive area, the cathode electrode including a first inclined portion having an end that is closer to the substrate than the second sub anode electrode but farther from the substrate than the end of the first inclined portion of the light emitting layer and extends along the first inclined portion of the light emitting layer, and a second portion of the cathode electrode that extends from the first inclined portion of the cathode electrode and contacts the second portion of the light emitting layer such that the second portion of the cathode electrode overlaps the second sub anode electrode and the second overcoat layer.

Embodiments of the disclosure may minimize or at least reduce aperture area loss by changing a sub-pixel structure from a horizontal-type structure to a vertical-type structure.

Embodiments of the disclosure may increase light extraction efficiency by applying side mirrors to a vertical sub-pixel structure.

Embodiments of the disclosure may provide a low-power display device by increasing light extraction efficiency.

### BRIEF DESCRIPTION OF DRAWINGS

FIG. 1 is a system configuration diagram illustrating a display device according to embodiments of the present disclosure.

FIG. 2 is a schematic plan diagram illustrating a single pixel illustrated in FIG. 1 according to embodiments of the present disclosure.

FIG. 3 is a schematic cross-sectional diagram illustrating the X portion of FIG. 2 according to embodiments of the present disclosure.

FIG. 4 is a schematic plan diagram illustrating a first embodiment of the X portion of FIG. 2 according to embodiments of the present disclosure.

FIG. 5 is a schematic plan diagram illustrating a second embodiment of the X portion of FIG. 2 according to embodiments of the present disclosure.

FIG. 6 is a schematic cross-sectional diagram taken along line I-I′ illustrated in FIG. 4 according to embodiments of the present disclosure.

FIG. 7 is a schematic cross-sectional diagram taken along line II-II′ illustrated in FIG. 4 according to embodiments of the present disclosure.

FIG. 8 is a schematic cross-sectional diagram taken along line III-III′ illustrated in FIG. 5 according to embodiments of the present disclosure.

FIGS. 9 and 10 are plan views illustrating repair points according to embodiments of the present disclosure.

FIG. 11 is a plan view illustrating a repair point according to embodiments of the present disclosure.

FIGS. 12 and 13 are cross-sectional diagrams illustrating repair points according to embodiments of the present disclosure.

FIGS. 14 and 15 are cross-sectional diagrams illustrating repair points according to embodiments of the present disclosure.

FIG. 16 is a schematic plan diagram illustrating a third embodiment of the X portion of FIG. 2 according to embodiments of the present disclosure.

FIG. 17 is a schematic plan diagram illustrating a fourth embodiment of the X portion of FIG. 2 according to embodiments of the present disclosure.

FIG. 18 is a schematic cross-sectional diagram taken along line IV-IV′ illustrated in FIG. 4 according to embodiments of the present disclosure.

FIG. 19 is a schematic cross-sectional diagram taken along line V-V′ illustrated in FIG. 4 according to embodiments of the present disclosure.

### DETAILED DESCRIPTION

In the following description of examples or embodiments of the present disclosure, reference will be made to the accompanying drawings in which it is shown by way of illustration specific examples or embodiments that may be implemented, and in which the same reference numerals and signs may be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including,” “having,” “containing,” “constituting,” “make up of” and “formed of” used herein are generally intended to allow other components to be added unless the terms are used with the term “only.” As used herein, singular forms are intended to include plural forms unless the context clearly indicates otherwise.

Terms, such as “first,” “second,” “A,” “B,” “(A)” or “(B)” may be used herein to describe elements of the present disclosure. Each of these terms is not used to define essence, order, sequence, number of elements, etc., but is used merely to distinguish the corresponding element from other elements.

When it is mentioned that a first element “is connected or coupled to,” “contacts or overlaps,” etc. a second element, it should be interpreted that, not only may the first element “be directly connected or coupled to” or “directly contact or overlap” the second element, but a third element may also be “interposed” between the first and second elements, or the first and second elements may “be connected or coupled to,” “contact or overlap,” etc. each other via a fourth element. Here, the second element may be included in at least one of two or more elements that “are connected or coupled to,” “contact or overlap,” etc. each other.

When time relative terms, such as “after,” “subsequent to,” “next,” “before” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes, etc. are mentioned, it should be considered that numerical values for elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can.”

Hereinafter, various embodiments of the present disclosure will be described in detail with reference to the accompanying drawings.

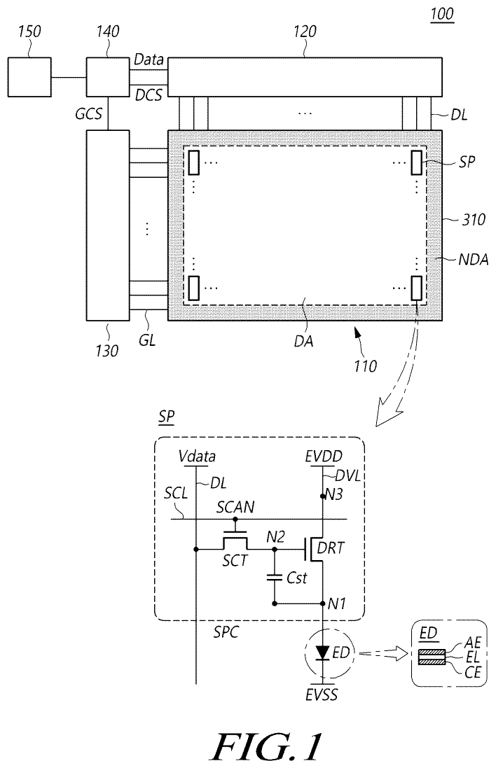

FIG. 1 is a system configuration diagram of a display device 100 according to embodiments of the present disclosure.

Referring to FIG. 1, a display drive system of the display device 100 according to embodiments of the present disclosure may include a display panel 110 and a display drive circuit for driving the display panel 110.

The display panel 110 may include a display area DA in which images are displayed and a non-display area NDA in which no image is displayed. The display panel 110 may include a plurality of sub-pixels SP arranged on a substrate 310 to display images.

The display panel 110 may include a plurality of signal wires arranged on the substrate 310. For example, the plurality of signal wiring may include data lines DL, gate lines GL, drive voltage lines, and the like.

Each of the plurality of data lines DL may be arranged extending in a first direction (e.g., column-wise or row-wise direction), and each of the plurality of gate lines GL may be arranged extending in a direction intersecting the first direction.

The display drive circuit may include a data drive circuit 120, a gate drive circuit 130, and the like, and may further include a controller 140 for controlling the data drive circuit 120 and the gate drive circuit 130.

The data drive circuit 120 may output data signals (also referred to as data voltages) corresponding to video signals to the plurality of data lines DL. The gate drive circuit 130 may generate gate signals and output the gate signals to the plurality of gate lines GL. The controller 140 may convert input video data from an external host 150 to video data suitable for a data signal format used in the data drive circuit 120 and supply the converted video data to the data drive circuit 120.

The data drive circuit 120 may include one or more source driver integrated circuits. For example, each source driver integrated circuit may be connected to the display panel 110 in a tape automated bonding (TAB) manner, may be connected to a bonding pad on the display panel 110 in a chip on glass (COG) or chip on panel (COP) manner, or may be connected to the display panel 110 in a chip on film (COF) manner.

The gate drive circuit 130 may be connected to the display panel 110 in a tape automated bonding (TAB) manner, connected to the bonding pad of the display panel 110 in a COG or COP manner, connected to the display panel 110 in a COF manner, or formed in the non-display area NDA of the display panel 110 in a gate in panel (GIP) type.

Referring to FIG. 1, in the display device 100 according to embodiments of the present disclosure, each sub-pixel SP may include an emitting diode ED and a pixel drive circuit SPC for driving the ED, and the pixel drive circuit SPC may include a drive transistor DRT, a scan transistor SCT, and a storage capacitor Cst.

The drive transistor DRT may control the current flowing to the emitting diode ED to drive the emitting diode ED. The scan transistor SCT may transmit a data voltage Vdata to a second node N2, which is a gate node of the drive transistor DRT. The storage capacitor Cst may be configured to maintain the voltage for a period of time.

The emitting diode ED may include an anode electrode AE and a cathode electrode CE, and an emission layer EL located between the anode electrode AE and the cathode electrode CE. The anode electrode AE may be a pixel electrode involved in the formation of the emitting diode ED of each sub-pixel SP, and may be electrically connected with a first node N1 of the drive transistor DRT. The cathode electrode CE may be a common electrode involved in the formation of the emitting diodes ED of all sub-pixels SP, and may be applied with a base voltage EVSS.

For example, the ED may be an organic light emitting diode (OLED), an inorganic light emitting diode (LED), or a quantum dot light emitting device, which is a self-illuminative semiconductor crystal.

The drive transistor DRT is a transistor for driving the emitting diode ED, and may include a first node N1, a second node N2, and a third node N3. The first node N1 may be a source or drain node, and may be electrically connected to an anode electrode AE of the emitting diode ED. The second node N2 is a gate node, and may be electrically connected to a source or drain node of the scan transistor SCT. The third node N3 may be a drain or source node, and may be electrically connected to a drive voltage line DVL that supplies a drive voltage EVDD. Below, for ease of explanation, it is exemplified that the first node N1 is a source node and the third node N3 is a drain node.

The scan transistor SCT may switch the connection between the data line DL and the second node N2 of the drive transistor DRT. The scan transistor SCT may control the connection between the second node N2 of the drive transistor DRT and a corresponding data line DL of the plurality of data lines DL in response to a scan signal SCAN supplied from the scan line SCL, which is a type of gate line GL.

The storage capacitor Cst may be configured between the first node N1 and the second node N2 of the drive transistor DRT.

The structure of the sub-pixel SP illustrated in FIG. 1 is for illustrative purposes only, and may further include one or more transistors DRT and capacitors Cst. Alternatively, each of the multiple sub-pixels may have the same structure, or some of the multiple sub-pixels may have different structures. Each of the drive transistor DRT and scan transistor SCT may be an n-type transistor or a p-type transistor.

On the other hand, the display device 100 according to embodiments of the present disclosure may have a top emission structure or a bottom emission structure. Below, it is exemplified that the display device has the top emission structure. For example, in the top emission structure, the anode electrode AE may be a reflective metal and the cathode electrode CE may be a transparent conductive film.

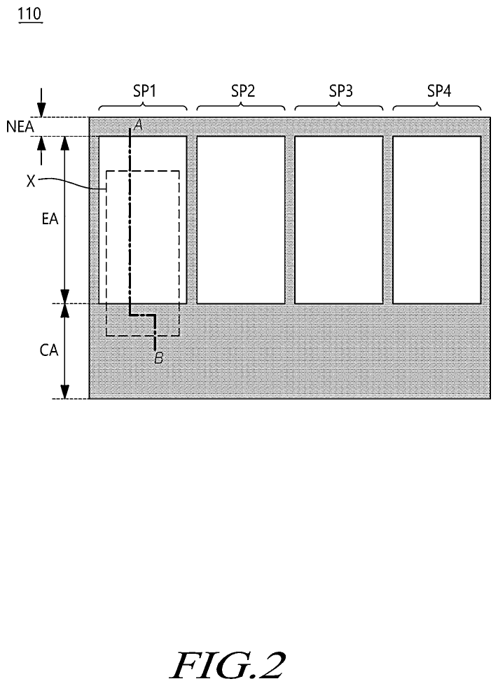

FIG. 2 is a plan view schematically illustrating a structure of a display device according to embodiments of the present disclosure. In the following description, the same or similar contents as described with reference to FIG. 1 will be omitted or briefly described.

Referring to FIG. 2, the display panel 110 according to embodiments of the present disclosure may include any display panel capable of outputting an image, such as a liquid crystal display panel including a liquid crystal layer, an organic field emitting display panel including an organic field emitting element, a quantum dot display panel including a quantum dot light emitting element, a micro LED display panel including a micro LED, a mini LED display panel including a mini LED, and the like.

The display panel 110 may include a non-emissive area NEA, an emissive area EA, and a circuit area CA. The pixels of the display panel 110 are illustrated as a structure including four sub-pixels SP1, SP2, SP3 and SP4, but the disclosure is not limited thereto.

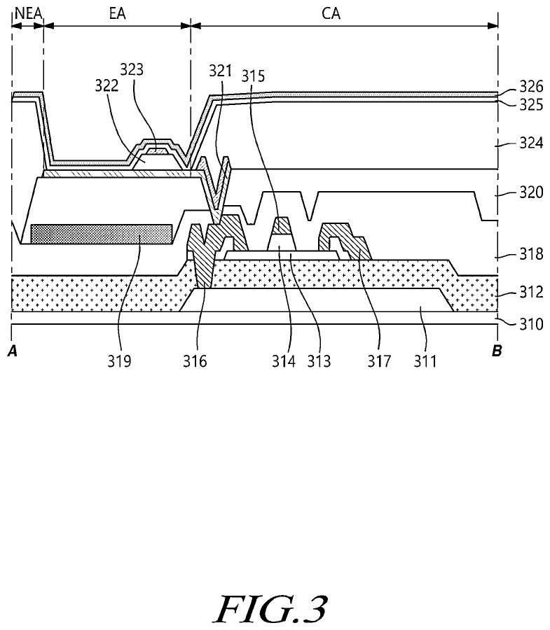

FIG. 3 is a schematic cross-sectional view of the X portion of FIG. 2. In the following description, the same or similar contents as described with reference to FIGS. 1 and 2 will be omitted or briefly described.

Referring to FIG. 3, the display device 100 according to embodiments of the present disclosure has a light-barrier layer 311 on a substrate 310. The light-barrier layer 311 serves to block (prevent) external light from entering a channel region (semiconductor region) of a thin-film transistor. The light-barrier layer 311 is selected as a metallic material that may block the transmission of light. While FIG. 3 illustrates the light-barrier layer 311 as a single-layer structure, the light-barrier layer 311 of the present disclosure may have a multi-layer structure or may be omitted depending on the structure of a thin-film transistor.

A buffer layer 312 is on the light-barrier layer 311 and the substrate 310. The buffer layer 312 serves to electrically isolate the light-barrier layer 311, prevent the effects of material leaking from the substrate, etc. The buffer layer 312 may include an inorganic insulating material such as silicon oxide (SiOx), silicon nitride (SiNx), or silicon oxynitride (SiON), but the present disclosure is not limited thereto. Optionally, the buffer layer 312 may be omitted in some cases.

While FIG. 3 illustrates the buffer layer 312 as being a single-layer structure, the buffer layer 502 of the present disclosure may have a multi-layer structure. If the buffer layer 312 has the multi-layer structure, it may have multiple layers alternately including layers of at least three inorganic insulating materials, such as silicon oxide (SiOx), silicon nitride (SiNx), or silicon oxynitride (SiON), but the present disclosure is not limited thereto.

A thin film transistor may include an active layer 313, a gate electrode 315, a drain electrode 316, and a source electrode 317. The active layer 313 of the thin film transistor may be arranged on the buffer layer 312.

The active layer 313 may include a channel region, a drain region, and a source region formed in the thin film transistor region of the circuit area CA of the sub-pixel. The drain region and the source region may be spaced apart from each other with the channel region arranged in between.

The active layer 313 may include a semiconductor material based on any one of amorphous silicon, polycrystalline silicon, oxide, and organic material, but the present disclosure is not limited thereto.

The gate insulating layer 314 may be formed on the channel region of the active layer 313. For example, the gate insulating layer 314 may be formed as an island only on the channel region of the active layer 313 or may be formed on the entire front surface of the substrate 310 or buffer layer 312 including the active layer 313. The gate insulating layer 314 may include an inorganic insulating material such as silicon oxide (SiOx), silicon nitride (SiNx), or silicon oxynitride (SiON), but the present disclosure is not limited thereto.

The gate electrode 315 may be formed on the gate insulating layer 314 to overlap the channel region of the active layer 313. The gate electrode 315 may include any one of metals such as aluminum (Al), gold (Au), silver (Ag), copper (Cu), tungsten (W), molybdenum (Mo), chromium (Cr), tantalum (Ta), titanium (Ti), or alloys thereof, but the present disclosure is not limited thereto. While FIG. 3 illustrates the gate electrode 315 as having a single layer structure, the gate electrode 315 of the present disclosure may have a multi-layer structure.

Each of the source electrode 317 and the drain electrode 316 may be made of the same metallic material. For example, the source electrode 317 and the drain electrode 316 may include any one of metals or alloys thereof, such as aluminum (Al), gold (Au), silver (Ag), copper (Cu), tungsten (W), molybdenum (Mo), chromium (Cr), tantalum (Ta), titanium (Ti), and the like, but the present disclosure is not limited thereto. They may also include other single metal layers, single layers of alloys, or multiple layers of two or more metals.

At least one of the drain electrode 316 or the source electrode 317 may be electrically coupled to the light-barrier layer 311 via a contact hole through the gate insulating layer 314 and the buffer layer 312.

A passivation layer 318 is arranged on the source electrode 317, the drain electrode 316, and the buffer layer 312. The passivation layer 318 may be formed throughout the circuit area CA and the emissive area EA. This passivation layer 318 may also be omitted. A color filter 319 may be arranged on the passivation layer 318.

The first overcoat layer 320 may be formed to have a relatively large thickness to mitigate a step. The first overcoat layer 320 may be arranged on top of the passivation layer 318. The first overcoat layer 320 may be formed of an organic film of e.g., acrylic resin, epoxy resin, phenolic resin, polyamide resin, polyimide resin, or the like. The first overcoat layer 320 may be arranged to cover the color filter 319. If the passivation layer 318 is omitted, the first overcoat layer 320 may be arranged on the substrate 310 to cover the circuit area. The first overcoat layer 320 may be formed over the entire of the circuit area CA, in which the thin film transistor is arranged, and the emissive area EA.

The 1-1 electrodes 321 (e.g., first sub anode electrodes) are formed on the first overcoat layer 320 to correspond to the emissive area EA and a portion of the circuit area CA of each sub-pixel. That is, the 1-1 electrode 321 is in the emissive area EA and the circuit area CA. While FIG. 3 illustrates a structure in which the 1-1 electrode 321 is a single layer, the present disclosure is not limited thereto. For example, the 1-1 electrode 321 may include a multi-layer structure with two or more layers. The 1-1 electrode 321 may be formed of a transparent conductive material (TCO) such as ITO, IZO, or a semi-transmissive conductive material such as magnesium (Mg), silver (Ag), or an alloy of magnesium (Mg) and silver (Ag), which may transmit light. The 1-1 electrode 321 may be expressed as a term of a pixel electrode or an anode electrode.

The second overcoat layer 322 may be arranged over the 1-1 electrode 321 so as to cover at least a portion of the 1-1 electrode 321 and correspond to the emissive area EA. That is, the second overcoat layer 322 is on a portion of the 1-1 electrode 321 in the emissive area EA and does not extend past ends of the 1-1 electrode 321 into the circuit area CA. The second overcoat layer 322 includes a flat upper surface and one or more inclined side surfaces that extend from the flat upper surface to the 1-1 electrode 321. The second overcoat layer 322 may be formed of the same material as the first overcoat layer 320, but the present disclosure is not limited thereto.

The 1-2 electrode 323 (e.g., a second sub anode electrode) is formed on the second overcoat layer 320 to correspond to the emissive area EA and a portion of the circuit area CA of each sub-pixel. As shown in FIG. 3, a first portion of the 1-2 electrode 323 is on the upper surface of the second overcoat layer 322 in the emissive area EA and a second portion of the 1-2 electrode 323 is on a portion of the 1-1 electrode 321 that is in the circuit area CA. That is, the second portion of the 1-2 electrode 323 contact the portion of the 1-1 electrode 321 that is in the contact hole. While FIG. 3 illustrates a structure in which the 1-2 electrode 323 is a single layer, the present disclosure is not limited thereto. For example, the 1-2 electrode 323 may include a multi-layer structure with two or more layers. The 1-2 electrode 323 may be formed of a transparent conductive material (TCO) such as ITO, IZO, or a semi-transmissive conductive material such as magnesium (Mg), silver (Ag), or an alloy of magnesium (Mg) and silver (Ag), which may transmit light. The 1-2 electrode 323 may be expressed as a term of a pixel electrode or an anode electrode.

On the other hand, embodiments of the present disclosure may include a vertical sub-pixel structure. The vertical sub-pixel structure may refer to a structure in which a 1-1 electrode 321 is arranged on a first overcoat layer 320, a second overcoat layer 322 is arranged on the 1-1 electrode 321 to cover at least a portion of the 1-1 electrode 321, and a second 1-2 electrode 323 is arranged on the second overcoat layer 322.

A bank layer 324 defines an emissive area EA for each of the plurality of sub-pixels. For example, in the display area DA, the area where the bank 520 is arranged may be the non-emissive area NEA, and the area where the bank 520 is not arranged in the display area DA may be the emissive area EA. The bank 324 may have a matrix-like grid structure throughout the substrate 310. The bank 324 exposes a portion of the 1-1 electrode 321. The bank 324 may include an opening that exposes a portion of the 1-1 electrode 321 to define an emissive area EA. As shown in FIG. 3, the second overcoat layer 322 is within the opening of the bank 324.

An organic light emitting layer 325 (e.g., a light emitting layer) may be arranged on top of the 1-1 electrode 321 exposed by the bank layer 324, the second overcoat layer 322, and the 1-2 electrode 323. In one embodiment, the organic light emitting layer 325 includes an inclined first portion having an end that contacts a portion of the 1-1 electrode 321 in the emissive area EA and extends toward the upper surface of the second overcoat layer 322 along the inclined side surface of the second overcoat layer 322. The organic light emitting layer 325 also includes a second portion that extends from the inclined first portion of the organic light emitting layer 325 and contacts the 1-2 electrode 323 and the upper surface of the second overcoat layer 322. While FIG. 3 illustrates a structure in which the organic light emitting layer 325 is a single layer, the present disclosure is not limited thereto. The organic light emitting layer 325 may also include multiple layers of organic material. Such an organic light emitting layer 325 may emit at least one of the colors, red, green, and blue. However, the present disclosure is not limited thereto, and the organic light emitting layer 325 may emit other colors, such as white, etc.

In the display device according to embodiments of the present disclosure, the emitting diode has been illustrated as an organic light-emitting element, but the emitting diode may be a quantum dot light-emitting element, a micro-LED, a mini LED, or the like, and the present disclosure is not limited thereto.

The second electrode 326 (e.g., the cathode electrode) may be arranged on the organic light emitting layer 325. In one embodiment, the second electrode 326 includes a first inclined portion having an end that is closer to the substrate 310 than the 1-2 electrode 323 but farther from the substrate 310 than the end of the first inclined portion of the organic light emitting layer 325 that contacts the 1-1 electrode 321 and extends along the first inclined portion of the organic light emitting layer 325. The second electrode 326 also includes a second portion that extends from the inclined first portion of the second electrode 326 and contacts the second portion of the organic light emitting layer 325 that contacts the upper surface of the second overcoat layer 322 and the 1-2 electrode 323 such that the second portion of the cathode electrode 326 overlaps the 1-2 electrode 323 and the second overcoat layer 322. The second electrode 326 may be formed of a transparent conductive material (TCO) such as ITO, IZO, or a semi-transmissive conductive material such as magnesium (Mg), silver (Ag), or an alloy of magnesium (Mg) and silver (Ag), which may transmit light. Such a second electrode 326 may be expressed as a term of a reflective electrode, a cathode electrode, or an opposing electrode. Further, while the second electrode 326 is illustrated in FIG. 3 as a single-layer structure, the disclosure is not limited thereto and may include a multi-layer structure of two or more layers.

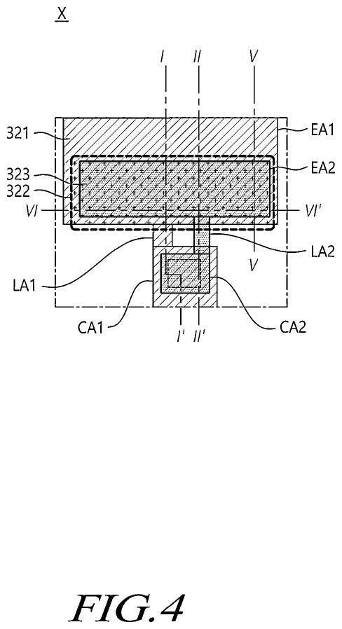

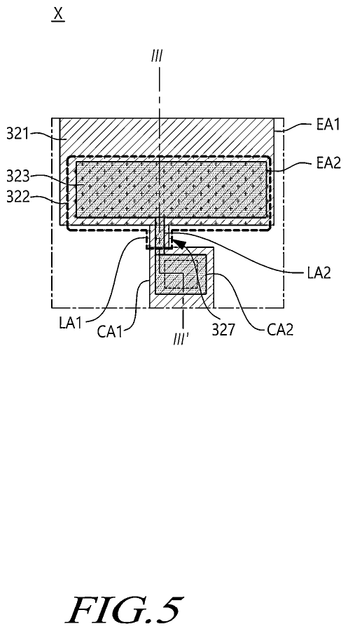

FIG. 4 is a schematic plan diagram illustrating a first embodiment of the X portion of FIG. 2, and FIG. 5 is a schematic plan diagram illustrating a second embodiment of the X portion of FIG. 2. In the following description, the same or similar contents as described with reference to FIGS. 1 to 3 will be omitted or briefly described.

To first describe the common features of FIGS. 4 and 5, a display device according to embodiments of the present disclosure may include a first overcoat layer 320, a 1-1 electrode 321, a second overcoat layer 322, a 1-2 electrode 323, a bank layer 324, an organic light emitting layer 325, and a second electrode 326.

Although not illustrated in FIGS. 4 and 5, the bank layer 324 may be configured to surround each of the emitters of the plurality of sub-pixels SP, since the bank layer is a region where no light is emitted. That is, the bank layer 324 may define an emissive area EA for each of the emitter or each of the plurality of sub-pixels SP.

The 1-1 electrode 321 may include a 1-1 emitter EA1, a 1-1 contact CA1, and a 1-1 connector LA1 connecting the 1-1 emitter EA1 and the 1-1 contact CA1 on the first overcoat layer 320. The 1-1 electrode 321 may include the 1-1 emitter EA1 corresponding to the emissive area EA, and the 1-1 contact CA1 corresponding to a portion of the circuit area CA and the 1-1 connector LA1. The 1-1 contact CA1 may also be electrically connected to the source electrode 317 or drain electrode 316 of the thin film transistor via contact hole through the first overcoat layer 320 and the passivation layer 318. Thus, the 1-1 electrode 321 contacts the thin film transistor via the contact hole.

The second overcoat layer 322 may be arranged over the 1-1 emitter EA1 and the 1-1 connector LA1 to cover at least a portion of the 1-1 emitter EA1 and the 1-1 connector LA1. The area of the second overcoat layer 322 may be formed to be larger than the area of the 1-2 emitter EA2 arranged on the upper surface of the second overcoat layer 322.

The 1-2 electrode 323 may include a 1-2 emitter EA2, a 1-2 contact CA2, and a 1-2 connector LA2 connecting the 1-2 emitter EA2 and the 1-2 contact CA2. The 1-2 electrode 323 includes the 1-2 emitter EA2 and the 1-2 connector LA2 corresponding to the emissive area EA, and the 1-2 connector LA2 and the 1-2 contact CA2 corresponding to a portion of the circuit area CA. The 1-2 emitter EA2 may be smaller in size than the 1-1 emitter EA1 in a plan view of the display device. The width of the 1-2 connector LA2 may be smaller than the width of the 1-2 emitter EA2 in the plan view of the display device. Further, the length of the 1-1 connector LA1 may be shorter than the length of the 1-2 connector LA2 in the plan view of the display device. At least a portion of the 1-2 connector LA2 may overlap with the 1-1 emitter EA1 and the 1-1 contact CA1.

The 1-1 contact CA1 may be electrically connected to the source electrode 317 or the drain electrode 316 of the thin film transistor via contact hole through the first overcoat layer 320 and the passivation layer 318. The area of the 1-2 contact CA2 may be smaller in size than the area of the 1-1 contact CA1. The 1-1 contact CA1 and the 1-2 contact CA2 may be arranged to overlap with each other. In addition, the 1-2 contact CA2 may be arranged on top of the 1-1 contact CA1.

Although the 1-2 emitter EA2 is illustrated in FIGS. 4 and 5 as a rectangular structure, the present disclosure is not limited thereto. For example, the 1-2 emitter EA2 may be formed in various shapes, such as circular, trident, and the like. Furthermore, the 1-2 emitter EA2 may be formed on a side closer to the 1-1 contact CA1 on the 1-1 emitter EA1, or may be formed on a side farthest from the 1-1 contact CA1.

Referring to FIG. 4, the 1-1 connector LA1 and the 1-2 connector LA2 may not overlap with each other. That is, the 1-1 connector LA1 and the 1-2 connector LA2 are non-overlapping with each other.

Referring to FIG. 5, the 1-1 connector LA1 and the 1-2 connector LA2 may be formed to overlap with each other. The width of the 1-1 connector LA1 may be equal to or greater than the width of the 1-1 emitter EA1.

Referring to FIG. 5, the second overcoat layer 322 may have a protrusion 327 that protrudes in the direction of the 1-1 contact CA1 and the 1-2 contact CA2. The protrusion 327 is formed to maximize the side mirror effect, and may vary in the extent to which the protrusion provides the side mirror effect.

Referring to FIGS. 4 and 5, the 1-1 connector CA1 and the 1-2 connector CA2 may or may not overlap, depending on the vertical repair aperture ratio. In the second embodiment, the 1-1 connector CA1 and the 1-2 connector CA2 are arranged to overlap with each other, which may have the effect of increasing the vertical repair aperture ratio.

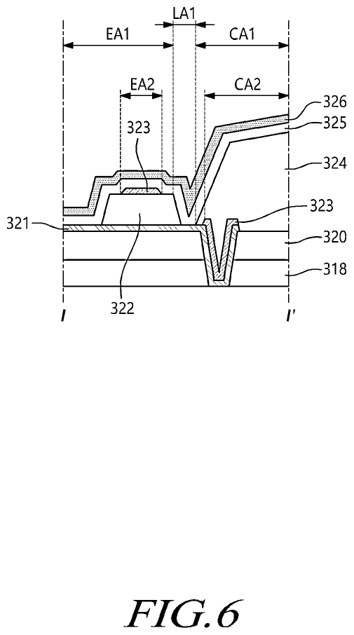

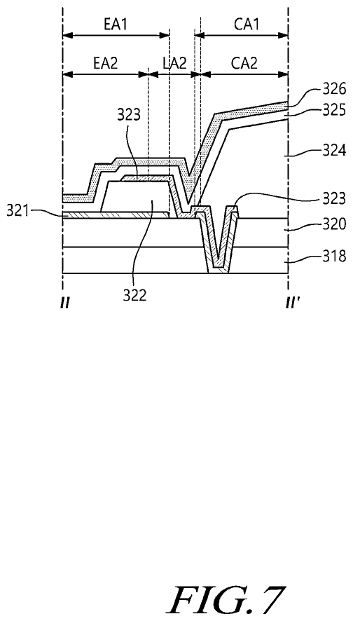

FIGS. 6 and 7 are cross-sectional diagrams illustrating a first embodiment of the present disclosure. Specifically, FIG. 6 is a schematic cross-sectional diagram taken along line I-I′ illustrated in FIG. 4, and FIG. 7 is a schematic cross-sectional diagram taken along line II-II′ illustrated in FIG. 4. In the following description, the same or similar contents as described with reference to FIGS. 1 to 5 will be omitted or briefly described.

Referring to FIG. 6, the 1-1 electrode 321 may include a 1-1 emitter EA1, a 1-1 contact CA1, and a 1-1 connector LA1 connecting the 1-1 emitter EA1 and the 1-1 contact CA1 on the first overcoat layer 320. The 1-1 connector LA1 may be in contact with the first overcoat layer 320. In addition, a bank layer 324 may be arranged on the 1-1 connector LA1.

The second overcoat layer 322 may be arranged to cover at least a portion of a side of the 1-1 emitter EA1 formed on a side close to the 1-1 contact CA1 where the 1-1 connector LA1 is not arranged. Further, the second overcoat layer 322 may provide a flat surface.

The 1-2 electrode 323 may include a 1-2 emitter EA2, a 1-2 contact CA2, and a 1-2 connector LA2 connecting the 1-2 emitter EA2 and the 1-2 contact CA2. The 1-2 emitter EA2 may be arranged on the second overcoat layer 322. The 1-1 contact CA1 and the 1-2 contact CA2 overlap with each other, and the 1-2 contact CA2 may be arranged on the 1-1 contact CA1. The 1-2 electrode 323 may not be arranged on the 1-1 connector LA1.

The bank layer 324 defining the emissive area EA may be formed to cover the 1-1 contact CA1. The bank layer 324 may be arranged such that it does not overlap with the second overcoat layer 322 in order to achieve side emission between the second overcoat layer 322 and the bank layer 324.

The organic light emitting layer 325 may be arranged to cover the emissive area EA exposed by the bank layer 324, and the bank layer 324. In addition, the second electrode 326 may be arranged on the organic light emitting layer 325.

Referring to FIG. 7, the 1-1 electrode 321 may include a 1-1 emitter EA1, a 1-1 contact CA1, and a 1-1 connector LA1 connecting the 1-1 emitter EA1 and the 1-1 contact CA1 on the first overcoat layer 320. The 1-1 electrode 321 may not be arranged on the 1-1 connector LA1.

The second overcoat layer 322 may be arranged to cover at least a portion of a side of the 1-1 emitter EA1 formed on a side close to the 1-1 contact CA1 where the 1-1 connector LA1 is not arranged. The second overcoat layer 322 may also provide a flat surface.

The 1-2 electrode 323 may include a 1-2 emitter EA2, a 1-2 contact CA2, and a 1-2 connector LA2 connecting the 1-2 emitter EA2 and the 1-2 contact CA2. The 1-2 emitter EA2 may be arranged on the second overcoat layer 322. The 1-2 connector LA2 may be arranged to abut (e.g., overlap) against the side of the second overcoat layer 322 and the side of the first overcoat layer 320. In addition, a bank layer 324 may be arranged on the 1-2 connector LA2. The 1-1 contact CA1 and the 1-2 contact CA2 overlap with each other, and the 1-2 contact CA2 may be arranged on the 1-1 contact CA1.

The bank layer 324 defining the emissive area EA may be formed to cover the 1-2 contact CA2. The bank layer 324 may be arranged such that it does not overlap with the second overcoat layer 322 in order to achieve side emission between the second overcoat layer 322 and the bank layer 324.

The organic light emitting layer 325 may be arranged to cover the emissive area EA exposed by the bank layer 324, and the bank layer 324. In addition, the second electrode 326 may be arranged on the organic light emitting layer 325.

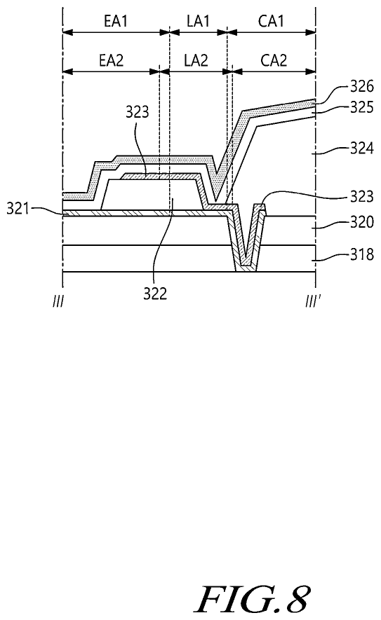

FIG. 8 is a cross-sectional diagram illustrating a second embodiment of the present disclosure. Specifically, FIG. 8 is a schematic cross-sectional diagram taken along line III-III′ illustrated in FIG. 5. In the following description, the same or similar contents as described with reference to FIGS. 1 to 7 will be omitted or briefly described.

Referring to FIG. 8, the 1-1 electrode 321 may include a 1-1 emitter EA1, a 1-1 contact CA1, and a 1-1 connector LA1 connecting the 1-1 emitter EA1 and the 1-1 contact CA1 on the first overcoat layer 320.

The second overcoat layer 322 may be arranged to cover at least a portion of a side of the 1-1 emitter EA1 formed on a side close to the 1-1 contact CA1 where the 1-1 connector LA1 is not arranged. That is, the second overcoat layer 322 extends past the side of the 1-1 emitter EA1 in a direction towards the 1-1 contact CA1 without extending to the 1-1 contact CA1. The second overcoat layer 322 may have a protrusion 327 that protrudes in the direction of the 1-1 contact CA1 and the 1-2 contact CA2, so that the second overcoat layer may be arranged to be longer than the second overcoat layer 322 illustrated in FIGS. 6 and 7.

The 1-2 electrode 323 may include a 1-2 emitter EA2, a 1-2 contact CA2, and a 1-2 connector LA2 connecting the 1-2 emitter EA2 and the 1-2 contact CA2. The 1-2 connector LA2 may be arranged to abut against a side of the second overcoat layer 322 and the 1-1 electrode 321. The 1-1 contact CA1 and the 1-2 contact CA2 overlap with each other, and the 1-2 contact CA2 may be arranged on the 1-1 contact CA1.

The bank layer 324 defining the emissive area EA may be formed to cover the 1-2 contact CA2. The bank layer 324 may be arranged so as not to overlap with the second overcoat layer 322 in order to achieve side emission between the second overcoat layer 322 and the bank layer 324.

The organic light emitting layer 325 may be arranged to cover the emissive area EA exposed by the bank layer 324, and the bank layer 324. In addition, the second electrode 326 may be arranged on the organic light emitting layer 325.

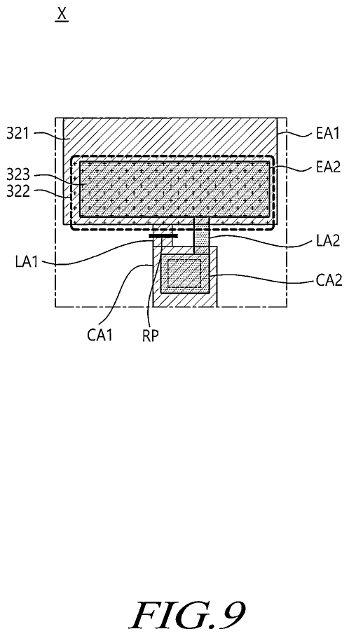

FIGS. 9, 10, and 11 are plan diagrams illustrating repair points RP according to first and second embodiments of the present disclosure. In the following description, the same or similar contents as described with reference to FIGS. 1 to 8 will be omitted or briefly described.

The display panel 110 according to embodiments of the present disclosure may be repaired by laser cutting at least a portion of the 1-1 connector LA1 and the 1-2 connector EA2 when any of the 1-1 emitter EA1 or the 1-2 emitter EA2 is a defective sub-pixel.

As an example, referring to FIG. 9, the display panel 110 according to embodiments of the present disclosure may be repaired by laser cutting the 1-1 connector LA1 when a defective sub-pixel occurs in the area where the 1-1 emitter EA1 is provided.

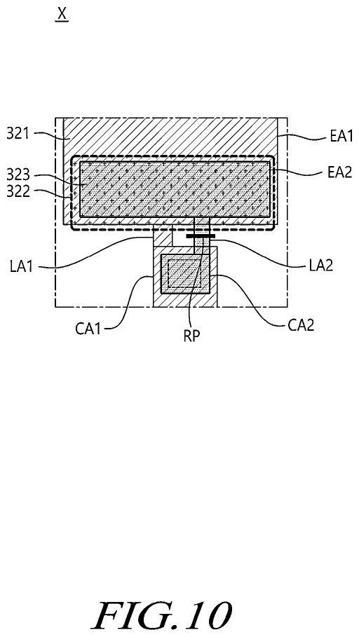

As another example, referring to FIG. 10, the display panel 110 according to embodiments of the present disclosure may be repaired by laser cutting the 1-2 connector LA2 when a defective sub-pixel occurs in the area where the 1-2 emitter EA2 is provided.

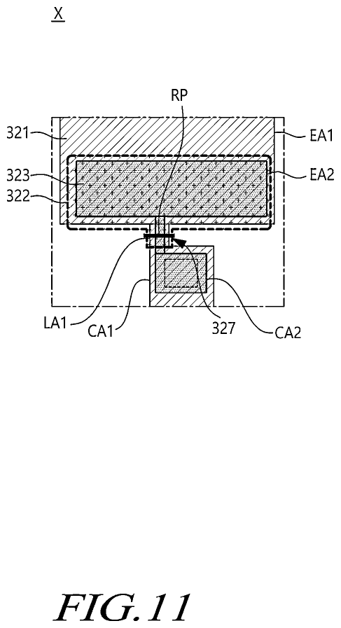

As a still another example, referring to FIG. 11, the 1-1 connector LA1 and the 1-2 connector LA2 may be irradiated with a laser when a defective sub-pixel occurs in the 1-1 emitter EA1 and the 1-2 emitter EA2.

The display panel 110 according to embodiments of the present disclosure may minimize the non-emissive area and reduce the light loss rate by short-circuiting only the corresponding division electrode by laser cutting, even when a defective sub-pixel occurs.

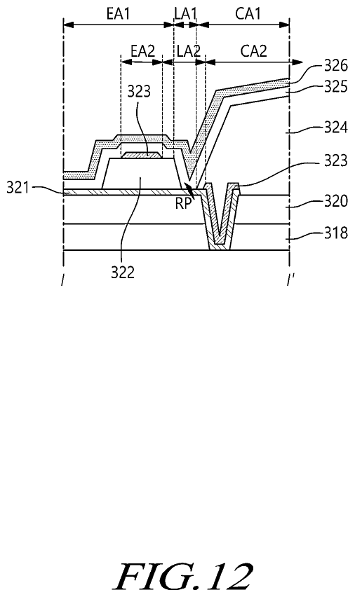

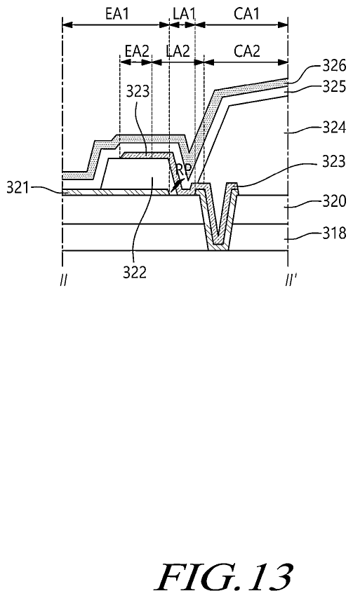

FIGS. 12 and 13 are cross-sectional diagrams illustrating repair locations according to embodiments of the present disclosure. In the following description, the same or similar contents as described with reference to FIGS. 1 to 11 will be omitted or briefly described.

The display panel 110 according to embodiments of the present disclosure may be repaired by laser cutting at least a portion of the 1-1 connector LA1 and the 1-2 connector EA2 when any of the 1-1 emitter EA1 or the 1-2 emitter EA2 is a defective sub-pixel. For example, if the 1-1 emitter EA1 is a defective sub-pixel, the 1-1 emitter may be repaired by irradiating the 1-1 connector LA1 with a laser to cut the 1-1 connector LA1. For example, if the 1-2 emitter EA2 is a defective subpixel, the 1-2 emitter may be repaired by irradiating the 1-2 connector LA2 with a laser to cut the 1-2 connector LA2. In this case, the laser may be irradiated to the top or bottom of the 1-1 connector LA1 or the 1-2 connector LA2.

As an example, referring to FIG. 12, the display panel 110 according to embodiments of the present disclosure may be repaired by irradiating the laser to the 1-1 connector LA1 to cut the 1-1 connector LA1 when a defective sub-pixel occurs in the area where the 1-1 emitter EA1 is provided. As shown in FIG. 12, a break (e.g., a cut) through an entire thickness of the 1-1 electrode 321 is formed by the laser when the sub-pixel is defective. In this case, the laser may be irradiated to the top of the 1-1 connector LA1, but the present disclosure is not limited thereto.

As another example, referring to FIG. 13, the display panel 110 according to embodiments of the present disclosure may be repaired by irradiating a laser to the 1-2 connector LA2 to cut the 1-2 connector LA2 when a defective sub-pixel occurs in the area where the 1-2 emitter EA2 is provided. As shown in FIG. 13, a break (e.g., a cut) through an entire thickness of the 1-2 electrode 323 is formed by the laser when the sub-pixel is defective. In this case, the laser may be irradiated to the top of the 1-2 connector LA2, but the present disclosure is not limited thereto.

The display panel 110 according to embodiments of the present disclosure may minimize the area of the non-emissive area and reduce the light loss rate by short-circuiting only the corresponding division electrode by laser cutting, even if a defective sub-pixel occurs.

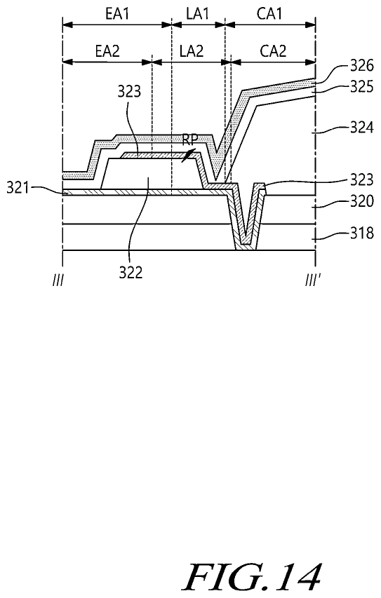

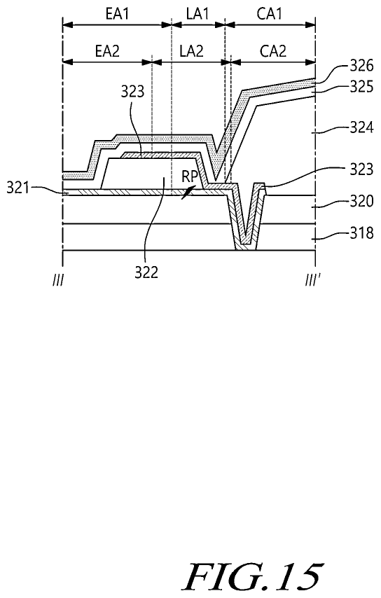

FIGS. 14 and 15 are cross-sectional diagrams illustrating repair locations according to a second embodiment of the present disclosure. In the following description, the same or similar contents as described with reference to FIGS. 1 to 13 will be omitted or briefly described.

The display panel 110 according to the second embodiment of the present disclosure may be repaired by laser cutting at least a portion of the 1-1 connector LA1 and the 1-2 connector EA2 when any of the 1-1 emitter EA1 or the 1-2 emitter EA2 is a defective sub-pixel. For example, if the 1-1 emitter EA1 is a defective sub-pixel, the 1-1 emitter may be repaired by irradiating the 1-1 connector LA1 with a laser to cut the 1-1 connector LA1. For example, if the 1-2 emitter EA2 is a defective sub-pixel, the 1-2 emitter may be repaired by irradiating the 1-2 connector LA2 with a laser to cut the 1-2 connector LA2. In this case, the laser may be irradiated to the top or bottom of the 1-1 connector LA1 or the 1-2 connector LA2.

As an example, referring to FIG. 14, the display panel 110 according to the second embodiment of the present disclosure may be repaired by irradiating the 1-2 connector LA2 with a laser to cut the 1-2 connector LA2 when a defective sub-pixel occurs in the area where the 1-2 emitter EA2 is provided. In this case, the laser may be irradiated to the top of the 1-2 connector LA2, but the present disclosure is not limited thereto.

As another example, referring to FIG. 15, the display panel 110 according to the second embodiment of the present disclosure may be repaired by irradiating a laser to the 1-1 connector LA1 and cutting the 1-1 connector LA1 when a defective sub-pixel occurs in the area where the 1-1 emitter EA1 is provided. In this case, the laser may be irradiated to the bottom of the 1-1 connector LA1, but the present disclosure is not limited thereto.

The display panel 110 according to the second embodiment of the present disclosure may minimize the non-emissive area and reduce the light loss rate by short-circuiting only the corresponding division electrode by laser cutting, even if a defective sub-pixel occurs.

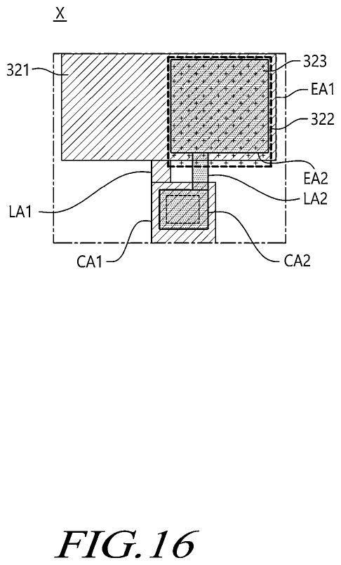

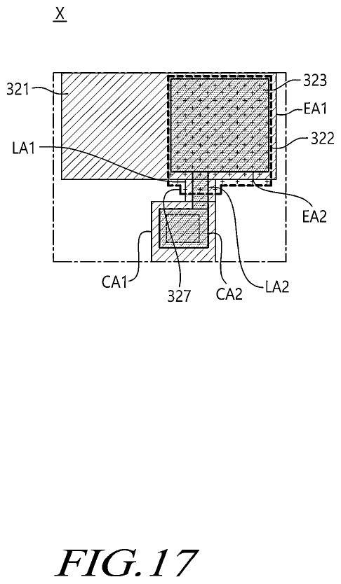

FIG. 16 is a schematic plan diagram illustrating a third embodiment of the X portion of FIG. 2, and FIG. 17 is a schematic plan diagram illustrating a fourth embodiment of the X portion of FIG. 2. In the following description, the same or similar contents as described with reference to FIGS. 1 to 15 will be omitted or briefly described.

To first describe the common features of FIGS. 16 and 17, the display device according to embodiments of the present disclosure may include a first overcoat layer 320, a 1-1 electrode 321, a second overcoat layer 322, a 1-2 electrode 323, a bank layer 324, an organic light emitting layer 325, and a second electrode 326.

Although not illustrated in FIGS. 16 and 17, the bank layer may be configured to surround each of the emitters of each of the plurality of sub-pixels SP with a non-emissive area. That is, the bank layer 324 may define an emissive area EA for each of the emitters or each of the plurality of sub-pixels SP.

The 1-1 electrode 321 may include a 1-1 emitter EA1, a 1-1 contact CA1, and a 1-1 connector LA1 connecting the 1-1 emitter EA1 and the 1-1 contact CA1 on the first overcoat layer 320. The 1-1 electrode 321 may include the 1-1 emitter EA1 corresponding to the emissive area EA, and the 1-1 contact CA1 corresponding to a portion of the circuit area CA and the 1-1 connector LA1. The 1-1 contact CA1 may also be electrically connected to the source electrode 317 and the drain electrode 316 of the thin film transistor via a contact hole through the first overcoat layer 320 and the passivation layer 318.

The second overcoat layer 322 may be arranged to cover at least a portion of a side of the 1-1 emitter EA1 formed on a side close to the 1-1 contact CA1 where the 1-1 connector LA1 is not arranged. The area of the second overcoat layer 322 may be formed to be larger than the area of the 1-2 emitter EA2 arranged on the top of the second overcoat layer 322.

The 1-2 electrode 323 may include a 1-2 emitter EA2, a 1-2 contact CA2, and a 1-2 connector LA2 connecting the 1-2 emitter EA2 and the 1-2 contact CA2. The 1-2 electrode 323 includes the 1-2 emitter EA2 and the 1-2 connector LA2 corresponding to the emissive area EA, and the 1-2 connector LA2 and the 1-2 contact CA2 corresponding to a portion of the circuit area CA. The 1-2 emitter EA2 may be smaller in size than the 1-1 emitter EA1. The width of the 1-2 connector LA2 may be smaller than the width of the 1-2 emitter EA2. Further, the length of the 1-1 connector LA1 may be shorter than the length of the 1-2 connector LA2. At least a portion of the 1-2 connector LA2 may overlap with the 1-1 emitter EA1 and the 1-1 contact CA1.

The 1-1 contact CA1 may be electrically connected to the source electrode 317 or the drain electrode 316 of the thin film transistor via a contact hole through the first overcoat layer 320 and the passivation layer 318. The area of the 1-2 contact CA2 may be smaller in size than the area of the 1-1 contact CA1. The 1-1 contact CA1 and the 1-2 contact CA2 may be arranged to overlap with each other. In addition, the 1-2 contact CA2 may be arranged on top of the 1-1 contact CA1.

Furthermore, in the third and fourth embodiments, the 1-2 emitter EA2 may be arranged to the left or right of the 1-1 emitter EA1. Further, although the 1-2 emitter EA2 is illustrated in FIGS. 16 and 17 as a rectangular structure, the present disclosure is not limited thereto. For example, the 1-2 emitter EA2 may be formed in various shapes, such as a circle, a trident, etc.

Referring to FIG. 16, the 1-1 connector LA1 and the 1-2 connector LA2 may not overlap with each other.

Referring to FIG. 17, the 1-1 connector LA1 and the 1-2 connector LA2 may be formed to overlap with each other. The width of the 1-1 connector LA1 may be equal to or greater than the width of the 1-1 emitter EA1.

Referring to FIG. 17, the second overcoat layer 322 may have a protrusion 327 that protrudes in the direction of the 1-1 contact CA1 and the 1-2 contact CA2. The protrusion 327 is formed to maximize the side mirror effect, and may vary in the extent to which the protrusion provides the side mirror effect.

Referring to FIGS. 16 and 17, the 1-1 connector CA1 and the 1-2 connector CA2 may or may not overlap with each other, depending on the vertical repair aperture ratio. In the second embodiment, the 1-1 connector CA1 and the 1-2 connector CA2 are arranged to overlap with each other, which may have the effect of increasing the vertical repair aperture ratio.

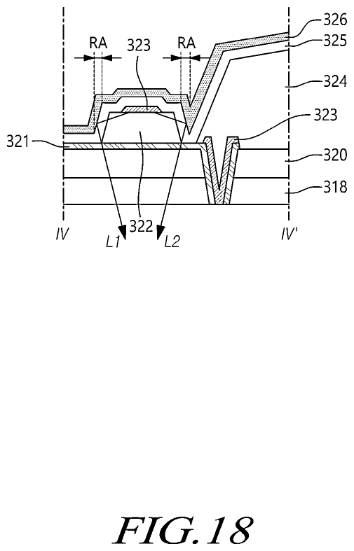

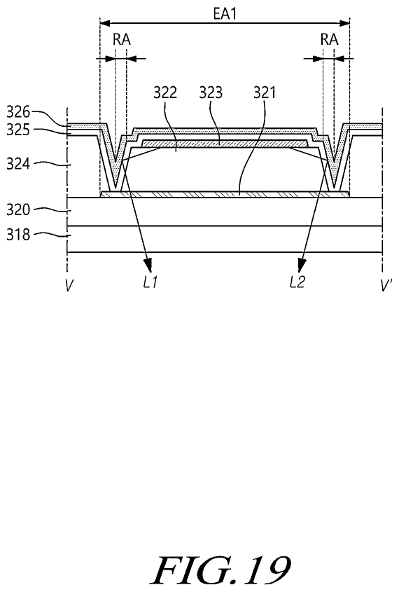

FIGS. 18 and 19 are diagrams illustrating a reflective path in which light is reflected and extracted in a frontal direction. Specifically, FIG. 18 is a schematic cross-sectional diagram taken along line IV-IV′ illustrated in FIG. 4. FIG. 19 is a schematic cross-sectional diagram taken along line V-V′ illustrated in FIG. 4. In the following description, the same or similar contents as described with reference to FIGS. 1 to 17 will be omitted or briefly described.

Referring to FIGS. 18 and 19, the bank layer 324 may be arranged so as not to overlap with the second overcoat layer 322 in order to provide side emission between the bank layer 324 and the second overcoat layer 322. That is, the bank layer 324 is spaced apart from the second overcoat layer 322 such that the bank layer 324 is not in contact with the second overcoat layer 322. The organic light emitting layer 325 and the second electrode 326 may be arranged between the second overcoat layer 322 and the bank layer 324 to form a reflective area RA capable of reflecting light. Furthermore, the sides of the second overcoat layer 322 may have a shape that is slanted (e.g., inclined) at a certain angle. That is, the sides of the second overcoat layer 322 are inclined at a predetermined angle. Therefore, the organic light emitting layer 325 and the second electrode 326 may be formed at an angle along the shape of the second overcoat layer 322 where an end of the second electrode 326 is closer to the substrate 310 than the 1-2 electrode 323. As a result, the reflected light L1, L2 may be extracted in the frontal direction by being reflected by the portion of the second electrode 326 that is between the second overcoat layer 322 and the bank layer 324, which has the effect of improving the frontal light extraction efficiency.

Referring to FIG. 19, the bank layer 324 may be formed to partially cover the left and right sides of the 1-1 emitter EA1 to define an emissive area. At this time, the second overcoat layer 322 may be arranged so as not to overlap with the bank layer 324, so that side emission may be achieved. Thus, the second overcoat layer 322 may be arranged inside the 1-1 emitter EA1. The organic light emitting layer 325 and the second electrode 326 may be arranged between the second overcoat layer 322 and the bank layer 324 to form a reflective area RA capable of reflecting light. Furthermore, the sides of the second overcoat layer 322 may have a shape that is slanted at a certain angle. Therefore, the organic light-emitting layer 325 and the second electrode 326 may be formed at an angle along the shape of the second overcoat layer 322, so that the reflected light L1, L2 may be extracted in the frontal direction, which has the effect of improving the frontal light extraction efficiency.

From the above description, embodiments of the present disclosure will be briefly described as follows.

A display device according to embodiments of the present disclosure may include a substrate, a plurality of sub-pixels arranged on the substrate and including an emissive area and a circuit area, a first overcoat layer arranged on the substrate, a 1-1 electrode arranged on the first overcoat layer, a second overcoat layer covering at least a portion of the 1-1 electrode, and a 1-2 electrode arranged on the second overcoat layer.

In the display device according to embodiments of the present disclosure, the 1-1 electrode may include a 1-1 emitter corresponding to the emissive area, a 1-1 contact corresponding to the circuit area, and a 1-1 connector connecting the 1-1 emitter and the 1-1 contact, and the 1-2 electrode may include a 1-2 emitter corresponding to the emissive area, a 1-2 contact corresponding to the circuit area, and a 1-2 connector connecting the 1-2 emitter and the 1-2 contact.

In the display device according to embodiments of the present disclosure, an area of the second overcoat layer may be larger than an area of the 1-2 emitter arranged on top of the second overcoat layer.

In the display device according to embodiments of the present disclosure, the second overcoat layer may cover at least a portion of a side of the 1-1 emitter formed on a side adjacent to the 1-1 contact in an area where the 1-1 contact is not arranged.

In the display device according to embodiments of the present disclosure, the 1-1 contact and the 1-2 contact may overlap with each other.

In the display device according to embodiments of the present disclosure, the 1-2 contact may be arranged on the 1-1 contact.

In the display device according to embodiments of the present disclosure, the 1-1 contact may be shorter in length than the 1-2 contact.

In the display device according to embodiments of the present disclosure, at least a portion of the 1-2 connector may overlap with the 1-1 emitter and the 1-1 contact.

In the display device according to embodiments of the present disclosure, the display device may include a bank layer defining an emissive area of each of a plurality of sub-pixels, an organic light emitting layer covering the 1-1 electrode, the second overcoat layer, the 1-2 electrode, and the bank layer, and a second electrode arranged on the organic light emitting layer.

In the display device according to embodiments of the present disclosure, the 1-1 connector and the 1-2 connector may not overlap with each other.

In the display device according to embodiments of the present disclosure, the 1-1 connector may abut against the first overcoat layer, and the 1-2 connector may abut against a side of the first overcoat layer and the second overcoat layer.

In the display device according to embodiments of the present disclosure, the 1-1 connector and the 1-2 connector may overlap with each other.

In the display device according to embodiments of the present disclosure, the second overcoat layer may further include a protrusion extending to an overlapped portion of the 1-1 connector and the 1-2 connector.

In the display device according to embodiments of the present disclosure, the 1-1 connector may abut against the first overcoat layer and the 1-2 connector may not abut against the first overcoat layer.

In the display device according to embodiments of the present disclosure, the width of the 1-1 connector may be equal to or greater than the width of the 1-2 connector.

In the display device according to embodiments of the present disclosure, the area of the 1-2 emitter may be smaller than the area of the 1-1 emitter.

In the display device according to embodiments of the present disclosure, the second electrode may be arranged on upper and side surfaces of the second overcoat layer to reflect light generated from the organic light emitting layer in the direction of the substrate.

In the display device according to embodiments of the present disclosure, the sub-pixel may be defective due to a failure of the first emitter and the first connector may include a break through an entire thickness of the first connector.

In the display device according to embodiments of the present disclosure, the sub-pixel may be defective due to a failure of the second emitter and the second connector may include a break through an entire thickness of the second connector.

A display device repairing method according to embodiments of the present disclosure includes: preparing a substrate; forming a plurality of sub-pixels arranged on the substrate and including an emissive area and a circuit area; forming a first overcoat layer arranged on the substrate; forming a 1-1 electrode arranged on the first overcoat layer; forming a second overcoat layer covering at least a portion of the 1-1 electrode, and forming a 1-2 electrode arranged on the second overcoat layer, wherein the emissive area includes a 1-1 emitter and a 1-2 emitter, and the method may further include irradiating the 1-1 connector with a laser beam to electrically break the 1-1 connector in the event of a failure of the 1-1 emitter, or irradiating the 1-2 connector with a laser beam to electrically break the 1-2 connector in the event of a failure of the 1-2 emitter.

A display device according to embodiments of the present disclosure may include a substrate having an emissive area in which an image is displayed and a circuit area; a transistor on the circuit area of the substrate; a first overcoat layer on the emissive area and the circuit area such that the first overcoat layer may be over the transistor in the circuit area; a first sub anode electrode in at least the emissive area, the first sub anode electrode connected to the transistor; a second overcoat layer on a portion of the first sub anode electrode in the emissive area without the second overcoat layer extending to the circuit area, the second overcoat layer including an upper surface and an inclined side surface that extends from the upper surface to the first sub anode electrode; a second sub anode electrode that may be on the upper surface of the second overcoat layer in the emissive area; a light emitting layer over the second sub anode electrode and the second overcoat layer in the emissive area, the light emitting layer including a first inclined portion having an end that may contact a portion of the first sub anode electrode in the emissive area and may extend toward the upper surface of the second overcoat layer along the inclined side surface of the second overcoat layer, and a second portion that may extend from the first inclined portion of the light emitting layer and may contact the second sub anode electrode and the upper surface of the second overcoat layer; and a cathode electrode on the light emitting layer in the emissive area, the cathode electrode including a first inclined portion having an end that may be closer to the substrate than the second sub anode electrode but farther from the substrate than the end of the first inclined portion of the light emitting layer and may extend along the first inclined portion of the light emitting layer, and a second portion of the cathode electrode that may extend from the first inclined portion of the cathode electrode and may contact the second portion of the light emitting layer such that the second portion of the cathode electrode may overlap the second sub anode electrode and the second overcoat layer.

In the display device according to embodiments of the present disclosure, a portion of the second sub anode electrode may be in the circuit area and the display device may further comprise a contact hole through the first overcoat layer in the circuit area. The first sub anode electrode may include a portion that may be in the contact hole and may contact the transistor through the contact hole and the portion of the second sub anode electrode may contact the portion of the first sub anode electrode in the contact hole.

In the display device according to embodiments of the present disclosure, the display device may further comprise a bank layer in the circuit area and may be spaced apart from the second overcoat layer, the bank layer having an opening that may define the emissive area. The second overcoat layer may be within the opening of the bank layer in the emissive area such that the first inclined portion of the light emitting layer and the first inclined portion of the cathode electrode may be between the second overcoat layer and the bank layer.

In the display device according to embodiments of the present disclosure, an area of the second overcoat layer may be larger than an area of the portion of the second sub anode electrode that may be on the upper surface of the second overcoat layer in a plan view of the display device.

In the display device according to embodiments of the present disclosure, the first sub anode electrode or the second sub anode electrode may include a break through an entire thickness of the first sub anode electrode or an entire thickness of the second sub anode electrode responsive to a subpixel that may include the first sub anode electrode and the second sub anode electrode being defective.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present disclosure. The above description and the accompanying drawings provide an example of the technical idea of the present disclosure for illustrative purposes only. That is, the disclosed embodiments are intended to illustrate the scope of the technical idea of the present disclosure.

What is claimed is:

1. A display device comprising:
a substrate;
a plurality of sub-pixels on the substrate, the plurality of sub-pixels comprising a sub-pixel including an emissive area and a circuit area;
a first overcoat layer on the substrate;
a first sub anode electrode on the first overcoat layer;
a second overcoat layer on a portion of the first sub anode electrode that is in the emissive area;
a second sub anode electrode on the second overcoat layer in the emissive area, the second sub anode electrode overlapping the first sub anode electrode in the emissive area;
an organic light emitting layer covering the first sub anode electrode, the second overcoat layer, and the second sub anode electrode in the emissive area; and
a cathode electrode on the organic light emitting layer in the emissive area.

2. The display device of claim 1, wherein the first sub anode electrode comprises:
a first emitter in the emissive area;
a first contact in the circuit area, the first contact contacting a transistor in the circuit area; and
a first connector that connects the first emitter and the first contact, and
wherein the second sub anode the first sub anode electrode or the second sub anode electrode includes a break through an entire thickness of the first sub anode electrode or an entire thickness of the second sub anode electrode responsive to a subpixel that includes the first sub anode electrode and the second sub anode electrode being defective second emitter in the emissive area;
a second contact in the circuit area, the second contact electrically connecting the second sub anode electrode to the transistor; and
a second connector connecting the second emitter and the second contact.

3. The display device of claim 2, wherein an area of the second overcoat layer is larger than an area of the second emitter that is on top of the second overcoat layer in a plan view of the display device.

4. The display device of claim 2, wherein the second overcoat layer extends past at least a portion of a side of the first emitter in a direction towards the first contact without extending to the first contact.

5. The display device of claim 2, wherein the first contact and the second contact overlap with each other in the circuit area.

6. The display device of claim 2, wherein the second contact is on the first contact in the circuit area.

7. The display device of claim 2, wherein the first contact has a length that is shorter than a length of the second contact in a plan view of the display device.

8. The display device of claim 2, wherein at least a portion of the second connector overlaps with the first emitter and the first contact.

9. The display device of claim 1, comprising:
a bank layer defining the emissive area of the sub-pixel;
wherein the organic light emitting layer covers the first sub anode electrode, the second overcoat layer, the second sub anode electrode, and the bank layer.

10. The display device of claim 2, wherein the first connector and the second connector are non-overlapping with each other.

11. The display device of claim 10, wherein the first connector contacts the first overcoat layer, and the second connector overlaps a side of the first overcoat layer and a side of the second overcoat layer.

12. The display device of claim 2, wherein the first connector and the second connector overlap with each other.

13. The display device of claim 12, wherein the second overcoat layer further comprises:
a protrusion extending to an a portion the first connector and a portion of the second connector that overlap each other in a plan view of the display device.

14. The display device of claim 13, wherein the first connector contacts the first overcoat layer and the second connector does not contact the first overcoat layer.

15. The display device of claim 14, wherein a width of the first connector is equal to or greater than a width of the second connector in a plan view of the display device.

16. The display device of claim 2, wherein an area of the second emitter is smaller than an area of the first emitter in a plan view of the display device.

17. The display device of claim 1, wherein the cathode electrode is on an upper surface and a side surface of the second overcoat layer and reflects light generated from the organic light emitting layer in a direction towards the substrate.

18. The display device of claim 2, wherein the sub-pixel is defective due to a failure of the first emitter and the first connector includes a break through an entire thickness of the first connector.

19. The display device of claim 2, wherein the sub-pixel is defective due to a failure of the second emitter and the second connector includes a break through an entire thickness of the second connector.

20. A display device comprising:
a substrate having an emissive area in which an image is displayed and a circuit area;
a transistor on the circuit area of the substrate;
a first overcoat layer on the emissive area and the circuit area such that the first overcoat layer is over the transistor in the circuit area;
a first sub anode electrode in at least the emissive area, the first sub anode electrode connected to the transistor;
a second overcoat layer on a portion of the first sub anode electrode in the emissive area without the second overcoat layer extending to the circuit area, the second overcoat layer including an upper surface and an inclined side surface that extends from the upper surface to the first sub anode electrode;
a second sub anode electrode that is on the upper surface of the second overcoat layer in the emissive area;
a light emitting layer over the second sub anode electrode and the second overcoat layer in the emissive area, the light emitting layer including a first inclined portion having an end that contacts a portion of the first sub anode electrode in the emissive area and extends toward the upper surface of the second overcoat layer along the inclined side surface of the second overcoat layer, and a second portion that extends from the first inclined portion of the light emitting layer and contacts the second sub anode electrode and the upper surface of the second overcoat layer; and
a cathode electrode on the light emitting layer in the emissive area, the cathode electrode including a first inclined portion having an end that is closer to the substrate than the second sub anode electrode but farther from the substrate than the end of the first inclined portion of the light emitting layer and extends along the first inclined portion of the light emitting layer, and a second portion of the cathode electrode that extends from the first inclined portion of the cathode electrode and contacts the second portion of the light emitting layer such that the second portion of the cathode electrode overlaps the second sub anode electrode and the second overcoat layer.

21. The display device of claim 20, wherein a portion of the second sub anode electrode is in the circuit area and the display device further comprises a contact hole through the first overcoat layer in the circuit area,
wherein the first sub anode electrode includes a portion that is in the contact hole and contacts the transistor through the contact hole and the portion of the second sub anode electrode contacts the portion of the first sub anode electrode in the contact hole.

22. The display device of claim 21, further comprising:
a bank layer in the circuit area and is spaced apart from the second overcoat layer, the bank layer having an opening that defines the emissive area,
wherein the second overcoat layer is within the opening of the bank layer in the emissive area such that the first inclined portion of the light emitting layer and the first inclined portion of the cathode electrode are between the second overcoat layer and the bank layer.

23. The display device of claim 20, wherein an area of the second overcoat layer is larger than an area of the portion of the second sub anode electrode that is on the upper surface of the second overcoat layer in a plan view of the display device.

24. The display device of claim 20, wherein the first sub anode electrode or the second sub anode electrode includes a break through an entire thickness of the first sub anode electrode or an entire thickness of the second sub anode electrode responsive to a subpixel that includes the first sub anode electrode and the second sub anode electrode being defective.
